(19) United States
(12) Patent Application Publication
(10) Pub. No.: US 2009/0042403 A1
(43) Pub. Date: Feb. 12, 2009

(54) METHOD FOR FABRICATING SEMICONDUCTOR DEVICE AND SEMICONDUCTOR DEVICE

(75) Inventors: Nobuo Aoi, Hyogo (JP); Hideo Nakagawa, Shiga (JP)

Correspondence Address: MCDERMOTT WILL & EMERY LLP, 600 13TH STREET, NW, WASHINGTON, DC, 20005-3096, US

(73) Assignee: MATSUSHITA ELECTRIC INDUSTRIAL CO., LTD., Osaka (JP)

(21) Appl. No.: 12/244,469

(22) Filed: Oct. 2, 2008

Related U.S. Application Data
(62) Division of application No. 11/471,491, filed on Jun. 21, 2006.

(30) Foreign Application Priority Data
Jun. 21, 2005 (JP) 2005-180604

(51) Int. Cl. H01L 21/31

(52) U.S. Cl. 438/762; 257/E21.24

(57) ABSTRACT

A method for fabricating a semiconductor device includes the steps of forming a nitrogen-containing layer in an exposed portion of a copper interconnect formed in an insulating film provided on a substrate; and forming an interlayer insulating film on the nitrogen-containing layer through plasma CVD performed by using, as a material, an organic silicon compound having a siloxane (Si—O—Si) bond.

### CROSS-REFERENCE TO RELATED APPLICATIONS

This application claims priority under 35 U.S.C. §119 on Patent Application No. 2005-180604 filed in Japan on June 21, 2005, the entire contents of which are hereby incorporated by reference.

### BACKGROUND OF THE INVENTION

The present invention relates to a method for fabricating a semiconductor device and the semiconductor device fabricated by the method, and more particularly, it relates to a method for fabricating a semiconductor device including a low dielectric constant insulating film having a function to prevent diffusion of copper ions and the semiconductor device fabricated by the method.

As an insulating film to be used as a copper diffusion preventing film in very large scale integration (VLSI) having copper interconnects, a SiN film, a SiON film, a SiC film, a SiCO film or the like is conventionally known, and all of these insulating films have a high dielectric constant of 4 or more. Therefore, even when a low dielectric constant film is used as an interlayer insulating film in a multilayered interconnect structure, the influence of the dielectric constant of the aforementioned insulating film used as the copper diffusion preventing film is dominant. Accordingly, the effect to reduce the dielectric constant by using the interlayer insulating film made of the low dielectric constant film in the multilayered interconnect structure is cancelled by the dielectric constant of the insulating film used as the copper diffusion preventing film, and hence, a sufficiently low value has not been realized as the effective dielectric constant of the whole multilayered interconnect structure.

In order to cope with such a problem, it is necessary to reduce the dielectric constant of an insulating film used as a copper diffusion preventing film or provide an interlayer insulating film made of a low dielectric constant film with a function as a copper diffusion preventing film.

As a conventional technique for reducing the dielectric constant of a copper diffusion preventing film, a method for forming a SiCN film through plasma CVD using trimethyl vinylsilane has been reported, and this SiCN film has a dielectric constant of 4. Alternatively, a method for forming a low dielectric constant interlayer insulating film having a function as a copper diffusion preventing film through plasma CVD using divinylsiloxane bis-benzocyclobutene has been reported, and this low dielectric constant film has a dielectric constant of approximately 2.7 (see, for example, Japanese Patent No. 3190886).

The SiCN film formed as a copper diffusion preventing film by using trimethyl vinylsilane has a dielectric constant of 4, and the dielectric constant is disadvantageously high.

Also, the low dielectric constant interlayer insulating film having the function as a copper diffusion preventing film formed by using divinylsiloxane bis-benzocyclobutene is disadvantageously expensive because divinylsiloxane bis-benzocyclobutene used as the material has a complicated chemical structure.

Furthermore, in order to perform deposition by the plasma CVD using divinylsiloxane bis-benzocyclobutene, it is necessary to vaporize the material through a thermal treatment, and a temperature of 150° C. or more is necessary for the vaporization. The divinylsiloxane bis-benzocyclobutene used as the material is easily polymerized through a thermal treatment at, for example, 150° C. or more, namely, easily thermally polymerized. Therefore, the material is polymerized in a carburetor and a solid or a liquid is produced within the carburetor so as to clog a pipe, resulting in lowering the working efficiency of a CVD system used for the deposition.

Moreover, the divinylsiloxane bis-benzocyclobutene used as the material is a thermally polymerizable material and is low at thermal stability. Furthermore, since the material includes a bifunctional monomer, a polymerized film formed by the plasma CVD using the monomer is basically constructed from a straight-chain polymer. Therefore, the interlayer insulating film formed by the plasma CVD using the divinylsiloxane bis-benzocyclobutene as the material is poor at mechanical strength (elasticity modulus and hardness), and hence, it is difficult to integrate as an interlayer insulating film of a multilayered interconnect structure.

### SUMMARY OF THE INVENTION

As a method for overcoming the above-described conventional problem, the following methods have been proposed: An interlayer insulating film that has a low dielectric constant (of 2.5), is thermally stable and has a function to prevent diffusion of copper ions is formed by an inexpensive method in which the working efficiency of a fabrication system is not lowered by using a disiloxane derivative having a simple chemical structure and having a substituent with two or more functional groups and with no thermal polymerization property; and an interlayer insulating film that is good at mechanical strength and has a function to prevent diffusion of copper ions is formed through three-dimensional polymerization using a disiloxane derivative having three or more functional groups.

In the interlayer insulating film having the copper ion diffusion preventing function formed by the plasma CVD using the disiloxane derivative having a simple chemical structure and having a substituent with two or more functional groups and with no thermal polymerization property, a siloxane site surrounded with organic sites functions as a site for trapping a copper ion. Accordingly, a structure in which a siloxane site is three-dimensionally surrounded with organic sites is the essential condition for providing the copper ion diffusion preventing function.

At the early stage of forming the interlayer insulating film by the plasma CVD, however, the structure in which the siloxane site working as the site for trapping a copper ion is three-dimensionally surrounded with organic sites is not completed yet, and hence, copper ions are easily diffused from a copper interconnect formed below the interlayer insulating film by the heat applied in the deposition process. Accordingly, even in the interlayer insulating film having the copper ion diffusion preventing function, the diffusion of copper ions cannot be sufficiently prevented at the early stage of the deposition, and hence, the reliability as the copper ion diffusion preventing film is disadvantageously lowered.

In consideration of the aforementioned conventional disadvantage, an object of the invention is preventing diffusion of copper ions from a copper interconnect at the early stage of deposition of a low dielectric constant interlayer insulating film having the copper ion diffusion preventing function.

According to an aspect of the invention, the method for fabricating a semiconductor device includes the steps of forming a nitrogen-containing layer in an exposed portion of a copper interconnect formed in an insulating film provided on a substrate; and forming an interlayer insulating film on the nitrogen-containing layer through plasma CVD performed by using, as a material, an organic silicon compound having a siloxane (Si—O—Si) bond.

In the method for fabricating a semiconductor device according to this aspect of the invention, the nitrogen-containing layer is formed before forming the interlayer insulating film, and therefore, diffusion of copper ions from the copper interconnect can be prevented at the early stage of the deposition of the interlayer insulating film. Also, the effect to reduce the dielectric constant attained by the interlayer insulating film is not cancelled by the dielectric constant of the nitrogen-containing layer, and hence, a good value can be realized as the effective dielectric constant of a multilayered interconnect structure. Furthermore, the diffusion of the copper ions from the copper interconnect can be completely prevented in the multilayered interconnect structure by the nitrogen-containing layer and the interlayer insulating film having the copper ion diffusion preventing function.

In the method for fabricating a semiconductor device, a layer of SiCN is preferably formed in the step of forming a nitrogen-containing layer.

Thus, the diffusion of copper ions from the copper interconnect can be definitely prevented at the early stage of the deposition of the interlayer insulating film.

In the method for fabricating a semiconductor device, an inert gas is preferably used as a diluent gas in the step of forming a nitrogen-containing layer.

Thus, plasma can be easily generated, and the nitrogen-containing layer can be easily formed.

In the method for fabricating a semiconductor device, the nitrogen-containing layer is preferably formed by nitriding the exposed portion through plasma processing performed in an atmosphere including nitrogen.

Thus, the diffusion of copper ions from the copper interconnect can be definitely prevented at the early stage of the deposition.

In the method for fabricating a semiconductor device, the nitrogen-containing layer is preferably formed by nitriding the exposed portion through plasma processing performing in an atmosphere including a nitrogen-containing compound.

Thus, the diffusion of copper ions from the copper interconnect can be definitely prevented at the early stage of the deposition.

In this case, the nitrogen-containing compound may be ammonia or an amine derivative.

In the method for fabricating a semiconductor device, the nitrogen-containing layer is preferably formed by implanting nitrogen ions into the exposed portion.

Thus, the diffusion of copper ions from the copper interconnect can be definitely prevented at the early stage of the deposition.

According to another aspect of the invention, the semiconductor device includes a nitrogen-containing layer formed in an exposed portion of a copper interconnect formed in an insulating film provided on a substrate; and an interlayer insulating film formed on the nitrogen-containing layer through plasma CVD performed by using, as a material, an organic silicon compound having a siloxane (Si—O—Si) bond.

In the semiconductor device according to this aspect of the invention, the nitrogen-containing layer is formed as an underlying layer of the interlayer insulating film, and therefore, diffusion of copper ions from the copper interconnect can be prevented at the early stage of deposition of the interlayer insulating film. Also, the effect to reduce the dielectric constant attained by the interlayer insulating film is not cancelled by the dielectric constant of the nitrogen-containing layer, and therefore, a good value can be realized as the effective dielectric constant of a multilayer interconnect structure. Moreover, the diffusion of copper ions from the copper interconnect can be completely prevented in the multilayered interconnect structure by the nitrogen-containing layer and the interlayer insulating film having the copper ion diffusion preventing function.

As described so far, according to the present invention, diffusion of copper ions from a copper interconnect can be prevented at the early stage of deposition of a low dielectric constant interlayer insulating film having the copper ion diffusion preventing function. Also, a good value can be realized as the effective dielectric constant of a multilayered interconnect structure. As a result, the lowering of the reliability of a semiconductor device can be suppressed.

### BRIEF DESCRIPTION OF THE DRAWINGS

FIGS. 1A, 1B and 1C are cross-sectional views for showing procedures in a method for fabricating a semiconductor device according to Embodiment 1 of the invention;

FIG. 2 is a schematic diagram of a CVD system used in the method for fabricating a semiconductor device of Embodiment 1;

FIGS. 3A, 3B and 3C are cross-sectional views for showing procedures in a method for fabricating a semiconductor device according to Embodiment 2 of the invention; and

FIGS. 4A, 4B and 4C are cross-sectional views for showing procedures in a method for fabricating a semiconductor device according to Embodiment 3 of the invention.

### DETAILED DESCRIPTION OF THE INVENTION

### EMBODIMENT 1

A method for fabricating a semiconductor device according to Embodiment 1 of the invention will now be described with reference to the accompanying drawings.

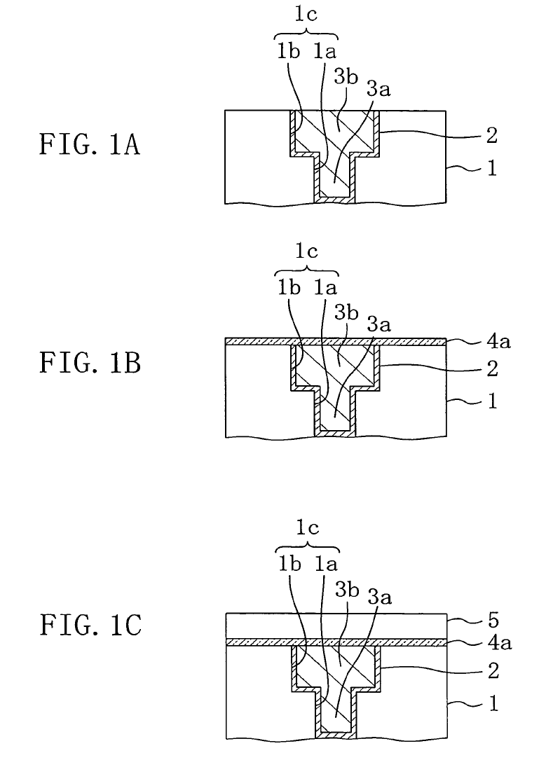

FIGS. 1A through 1C are cross-sectional views for showing procedures in the method for fabricating a semiconductor device of Embodiment 1.

First, as shown in FIG. 1A, a recess le corresponding to a dual damascene interconnect groove composed of a via hole 1a and an interconnect groove 1b communicated with the via hole 1a is formed in a first interlayer insulating film 1 formed on a semiconductor substrate not shown and made of a low dielectric constant material (a low-k material). Thereafter, a barrier film 2 is formed on the inner wall and the bottom of the recess 1c, so as to prevent the first interlayer insulating film 1 from being in direct contact with an interconnect plug 3a and a copper interconnect 3b described below. Then, copper is filled in the recess 1c where the barrier film 2 has been formed and an unnecessary portion of the copper is removed through polishing by CMP. Thus, the interconnect plug 3a is formed in the via hole 1a and the copper interconnect 3b is formed in the interconnect groove 1b. Although a dual damascene method is herein employed for forming the interconnect plug 3a and the copper interconnect 3b, a single damascene method can be employed instead.

Next, as shown in FIG. 1B, a SiCN film 4a is deposited in a thickness of 2 nm on the first interlayer insulating film 1 and the copper interconnect 3b by plasma CVD.

Thereafter, as shown in FIG. 1C, a second interlayer insulating film 5 with a low dielectric constant having a copper ion diffusion preventing function is formed on the SiCN film 4a. Now, the method for forming the second interlayer insulating film 5 will be specifically described.

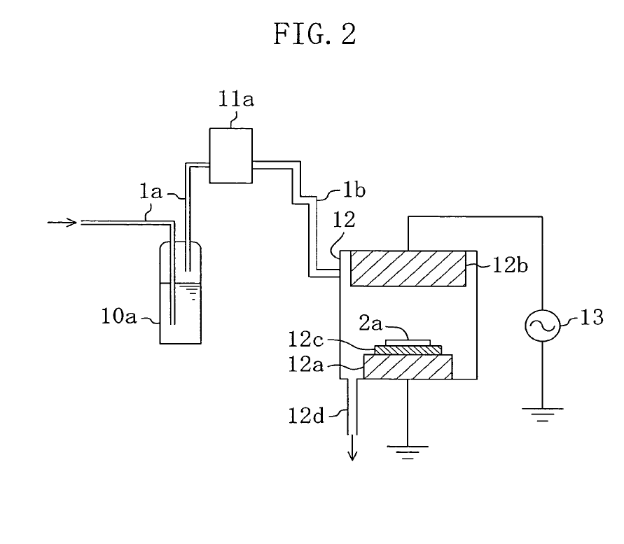

The second interlayer insulating film 5 is formed by using a general diode parallel plate cathode coupled plasma enhanced CVD system having an architecture, for example, schematically shown in FIG. 2. Also, an organic silicon compound such as 1,3-diphenyl-1,1,3,3-tetramethyldisiloxane is used as a CVD material.

First, 1,3-diphenyl-1,1,3,3-tetramethyldisiloxane used as the CVD material is filled in a pressure vessel 10a through a gas supply pipe 1a. Then, the 1,3-diphenyl-1,1,3,3-tetramethyldisiloxane filled in the pressure vessel 10a is transported to a carburetor 11a with pressure of He and is vaporized in the carburetor 11a at 180° C. Then, the vaporized 1,3-diphenyl-1,1,3,3-tetramethyldisiloxane is introduced into a deposition chamber 12. In the deposition chamber 12, a lower electrode 12a is disposed on the bottom and an upper electrode 12b is disposed above the lower electrode 12a, and a target substrate 2a is placed on a substrate supporting portion 12c provided on the lower electrode 12a. Also, the deposition chamber 12 is provided with an outlet 12d on a side of the lower electrode 12a so that a gas obtained after a reaction or a gas having not sufficiently contributed to the reaction can be successively exhausted.

In this embodiment, with the pressure within the deposition chamber 12 set to 400 Pa and the substrate temperature set to 400° C., while introducing the 1,3-diphenyl-1,1,3,3-tetramethyldisiloxane into the deposition chamber 12 at a flow rate of 0.1 g/min., power of 0.2 W/cm² is applied to the lower electrode 12a and the upper electrode 12b by a radio frequency (RF) power source 13 for plasma polymerization. During the plasma polymerization, in the 1,3-diphenyl-1,1,3,3-tetramethyldisiloxane used as the CVD material, for example, a phenyl group is changed into a radical by the plasma, and the phenyl group changed to the radical is copolymerized with tetramethylsilane. Thus, the second interlayer insulating film 5 having a good copper ion diffusion preventing function and a low dielectric constant (of 2.5) is formed. Specifically, the second interlayer insulating film 5 has a main chain in which a siloxane site and an organic molecule site are alternately bonded, and has a film structure in which siloxane bonds are dispersed in a network of an organic polymer, and therefore, it is good at the copper ion diffusion preventing function. Since the 1,3-diphenyl-1,1,3,3-tetramethyldisiloxane is minimally thermally polymerized through vaporization at 180° C., it can be introduced into the deposition chamber 12 in the form of a monomer, and hence, lowering of the working efficiency of the CVD system caused by clogging or the like can be prevented.

Herein, the description is made by exemplifying the case where organic groups bonded to silicon of the disiloxane used as the CVD material are a phenyl group and a methyl group. Since a radical of an alkyl group tends to be unstable, when an alkyl group is used, bond disconnection between silicon and an organic group is easily caused and hence the yield of radical polymerization may be low. However, when at least any group selected from a group of organic groups consisting of an ethyl group, a propyl group, a butyl group (including a cyclobutyl group), a pentyl group (including a cyclopentyl group), a hexyl group (including a cyclohexyl group), a vinyl group, a derivative of a vinyl group, a phenyl group and a derivative of a phenyl group is used as the organic group bonded to silicon of the disiloxane, a film can be advantageously formed through the radical polymerization because all of these organic groups are more easily changed into radicals than a methyl group. Therefore, a film structure in which siloxane bonds are dispersed in a network of an organic polymer can be thus sufficiently obtained. In particular, a vinyl group, a phenyl group and a derivative of a phenyl group have a π bond capable of easily giving/receiving electrons and hence are effectively used in the plasma enhanced radical polymerization.

In this manner, in the method for fabricating a semiconductor device of Embodiment 1, the diffusion of copper ions from the copper interconnect 3b can be prevented at the early stage of the deposition as well as the lowering of the effective dielectric constant of a multilayered interconnect structure can be prevented. Specifically, since a structure in which a siloxane site working as a site for trapping a copper ion is three-dimensionally surrounded with organic sites is not completed at the early stage of the deposition of the second interlayer insulating film 5, copper ions are easily diffused from the copper interconnect 3b by the heat applied in the deposition process. Therefore, although the copper ion diffusion preventing function is poor at this point, since the SiCN film is formed before forming the second interlayer insulating film 5, the diffusion of the copper ions can be prevented at the early stage of the deposition. After the early stage of the deposition of the second interlayer insulating film 5, the structure in which the siloxane site is three-dimensionally surrounded with the organic sites is completed, and hence, the diffusion of the copper ions from the copper interconnect 3b can be prevented. Furthermore, since the thickness of the SiCN film 4a is much smaller than the thickness of the second interlayer insulating film 5, the effective dielectric constant of the multilayered interconnect structure is not dominated by the dielectric constant of the SiCN film 4a. Accordingly, the effective dielectric constant of the multilayered interconnect structure can be reduced.

As a result, according to the method for fabricating a semiconductor device of Embodiment 1 of the invention, the diffusion of the copper ions from the copper interconnect 3b can be completely prevented by the SiCN film 4a and the second interlayer insulating film 5 in the multilayered interconnect structure and the effective dielectric constant of the multilayered interconnect structure can be suppressed to a small value.

Although the SiCN film 4a is used in this embodiment in consideration of the copper ion diffusion preventing function, a SiN film, a SiON film, a SiC film, a SiCO film or the like may be formed instead of the SiCN film 4a.

### EMBODIMENT 2

A method for fabricating a semiconductor device according to Embodiment 2 of the invention will now be described with reference to the accompanying drawings.

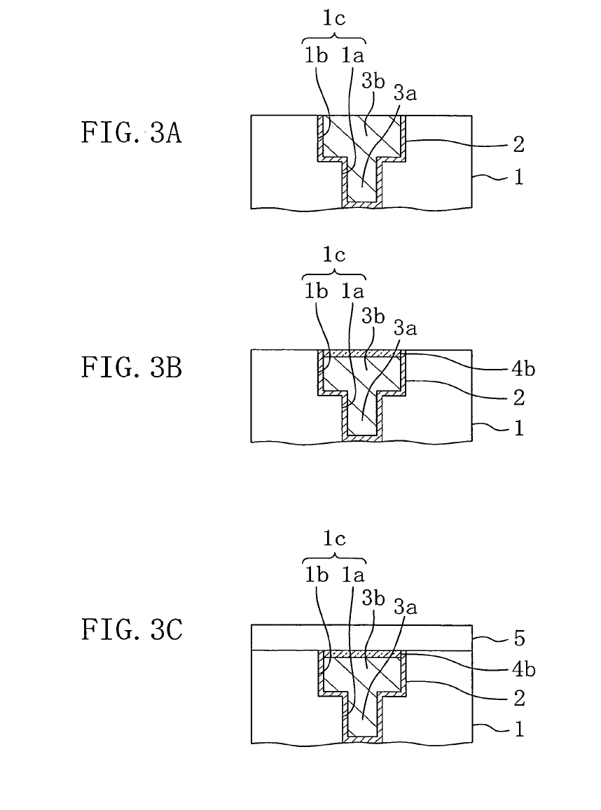

FIGS. 3A through 3C are cross-sectional views for showing procedures in the method for fabricating a semiconductor device of Embodiment 2.

First, as shown in FIG. 3A, a recess 1c corresponding to a dual damascene interconnect groove composed of a via hole 1a and an interconnect groove 1b communicated with the via hole 1a is formed in a first interlayer insulating film 1 formed on a semiconductor substrate not shown and made of a low dielectric constant material (a low-k material). Thereafter, a barrier film 2 is formed on the inner wall and the bottom of the recess 1c so as to prevent the first interlayer insulating film 1 from being in direct contact with an interconnect plug 3a and a copper interconnect 3b described below. Then, copper is filled within the recess 1c where the barrier film 2 has been formed and an unnecessary portion of the copper is removed through polishing by the CMP. Thus, the interconnect plug 3a is formed in the via hole 1a and the copper interconnect 3b is formed in the interconnect groove 1b. Although the dual damascene method is herein employed for forming the interconnect plug 3a and the copper interconnect 3b, a single damascene method may be employed instead.

Next, as shown in FIG. 3B, an exposed portion of the copper interconnect 3b is nitrided through plasma processing performed in an atmosphere including nitrogen, so as to form a plasma nitride layer 4b in a surface portion of the copper interconnect 3b. Although the plasma processing is herein performed in an atmosphere including nitrogen, the nitriding plasma processing may be performed with an inert gas such as helium or argon added as a diluent gas so that the plasma can be easily generated. Also, when an amine derivative such as monomethylsilane, dimethylamine or trimethylamine is used instead of nitrogen, the same effect can be attained.

Next, as shown in FIG. 3C, a second interlayer insulating film 5 with a low dielectric constant having the copper ion diffusion preventing function is deposited on the plasma nitride layer 4b and the first interlayer insulating film 1. The method for forming the second interlayer insulating film 5 and the effect attained by the second interlayer insulating film 5 thus formed are the same as those described in Embodiment 1.

In this manner, according to the method for fabricating a semiconductor device of Embodiment 2 of the invention, the diffusion of copper ions from the copper interconnect 3b can be prevented at the early stage of the deposition as well as the lowering of the effective dielectric constant of a multilayered interconnect structure can be prevented. Specifically, since a structure in which a siloxane site working as a site for trapping a copper ion is three-dimensionally surrounded with organic sites is not completed at the early stage of the deposition of the second interlayer insulating film 5, copper ions are easily diffused from the copper interconnect 3b by the heat applied in the deposition process. Therefore, although the copper ion diffusion preventing function is poor at this point, since the plasma nitride layer 4b is formed before forming the second interlayer insulating film 5, the diffusion of the copper ions can be prevented at the early stage of the deposition. After the early stage of the deposition of the second interlayer insulating film 5, the structure in which the siloxane site is three-dimensionally surrounded with the organic sites is completed, and hence, the diffusion of the copper ions from the copper interconnect 3b can be prevented. Furthermore, since the thickness of the plasma nitride layer 4b is much smaller than the thickness of the second interlayer insulating film 5, the effective dielectric constant of the multilayered interconnect structure is not dominated by the dielectric constant of the plasma nitride layer 4b. Accordingly, the effective dielectric constant of the multilayered interconnect structure can be reduced.

As a result, according to the method for fabricating a semiconductor device of Embodiment 2 of the invention, the diffusion of the copper ions from the copper interconnect 3b can be completely prevented by the plasma nitride layer 4b and the second interlayer insulating film 5 in the multilayered interconnect structure and the effective dielectric constant of the multilayered interconnect structure can be suppressed to a small value. Thus, the reliability of the semiconductor device can be prevented from lowering.

### EMBODIMENT 3

A method for fabricating a semiconductor device according to Embodiment 3 of the invention will now be described with reference to the accompanying drawings.

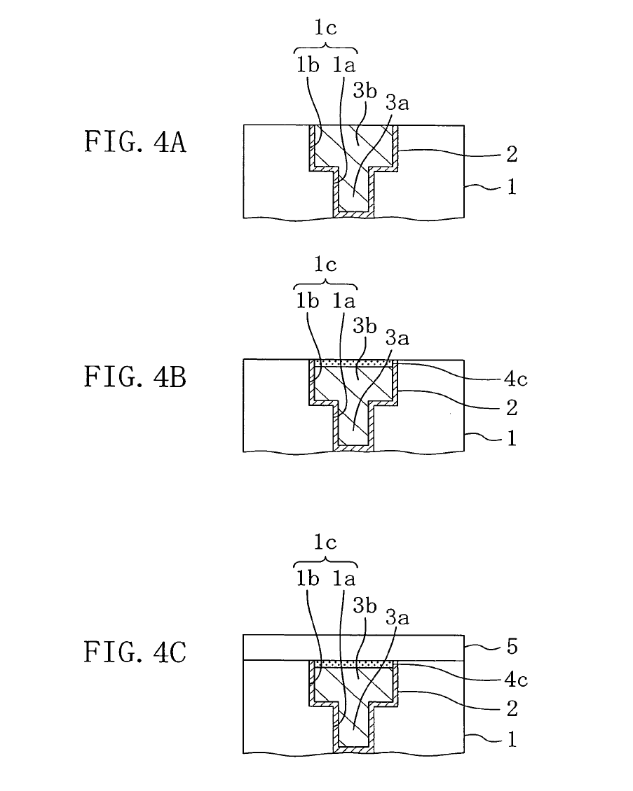

FIGS. 4A through 4C are cross-sectional views for showing procedures in the method for fabricating a semiconductor device of Embodiment 3.

First, as shown in FIG. 4A, a recess 1c corresponding to a dual damascene interconnect groove composed of a via hole 1a and an interconnect groove 1b communicated with the via hole 1a is formed in a first interlayer insulating film 1 formed on a semiconductor substrate not shown and made of a low dielectric constant material (a low-k material). Thereafter, a barrier film 2 is formed on the inner wall and the bottom of the recess 1c, so as to prevent the first interlayer insulating film 1 from being in direct contact with an interconnect plug 3a and a copper interconnect 3b described below. Then, copper is filled within the recess 1c where the barrier film 2 has been formed and an unnecessary portion of the copper is removed through polishing by the CMP. Thus, the interconnect plug 3a is formed in the via hole 1a and the copper interconnect 3b is formed in the interconnect groove 1b. Although the dual damascene method is herein employed for forming the interconnect plug 3a and the copper interconnect 3b, a single damascene method may be employed instead.

Next, as shown in FIG. 4B, nitrogen ions are implanted into an exposed portion of the copper interconnect 3b, so as to form a nitrogen ion implanted layer 4c in a surface portion of the copper interconnect 3b.

Next, as shown in FIG. 4C, a second interlayer insulating film 5 with a low dielectric constant having the copper ion diffusion preventing function is deposited on the nitrogen ion implanted layer 4c and the first interlayer insulating film 1. The method for forming the second interlayer insulating film 5 and the effect attained by the second interlayer insulating film 5 thus formed are the same as those described in Embodiment 1.

In this manner, according to the method for fabricating a semiconductor device of Embodiment 3 of the invention, the diffusion of copper ions from the copper interconnect 3b can be prevented at the early stage of the deposition as well as the lowering of the effective dielectric constant of a multilayered interconnect structure can be prevented. Specifically, since a structure in which a siloxane site working as a site for trapping a copper ion is three-dimensionally surrounded with organic sites is not completed at the early stage of the deposition of the second interlayer insulating film 5, copper ions are easily diffused from the copper interconnect 3b by the heat applied in the deposition process. Therefore, although the copper ion diffusion preventing function is poor at this point, since the nitrogen ion implanted layer 4c is formed before forming the second interlayer insulating film 5, the diffusion of the copper ions can be prevented at the early stage of the deposition. After the early stage of the deposition of the second interlayer insulating film 5, the structure in which the siloxane site is three-dimensionally surrounded with the organic sites is completed, and hence, the diffusion of the copper ions from the copper interconnect 3b can be prevented. Furthermore, since the thickness of the nitrogen ion implanted layer 4c is much smaller than the thickness of the second interlayer insulating film 5, the effective dielectric constant of the multilayered interconnect structure is not dominated by the dielectric constant of the nitrogen ion implanted layer 4c. Accordingly, the effective dielectric constant of the multilayered interconnect structure can be reduced.

As a result, according to the method for fabricating a semiconductor device of Embodiment 3 of the invention, the diffusion of the copper ions from the copper interconnect 3b can be completely prevented by the nitrogen ion implanted layer 4c and the second interlayer insulating film 5 in the multilayered interconnect structure and the effective dielectric constant of the multilayered interconnect structure can be suppressed to a small value. Thus, the reliability of the semiconductor device can be prevented from lowering.

As described above, the present invention is useful for, for example, a method for forming a low dielectric constant film having a copper ion diffusion preventing function in a multilayered interconnect structure.

1. A method for fabricating a semiconductor device comprising the steps of:
forming a nitrogen-containing layer in an exposed portion of a copper interconnect formed in an insulating film provided on a substrate; and
forming an interlayer insulating film on said nitrogen-containing layer through plasma CVD performed by using, as a material, an organic silicon compound having a siloxane (Si—O—Si) bond.

2. The method for fabricating a semiconductor device of claim 1,
wherein a layer of SiCN is formed in the step of forming a nitrogen-containing layer.

3. The method for fabricating a semiconductor device of claim 2,
wherein an inert gas is used as a diluent gas in the step of forming a nitrogen-containing layer.

4. The method for fabricating a semiconductor device of claim 1,
wherein said nitrogen-containing layer is formed by nitriding said exposed portion through plasma processing performed in an atmosphere including nitrogen.

5. The method for fabricating a semiconductor device of claim 1,
wherein said nitrogen-containing layer is formed by nitriding said exposed portion through plasma processing performing in an atmosphere including a nitrogen-containing compound.

6. The method for fabricating a semiconductor device of claim 5,
wherein said nitrogen-containing compound is ammonia or an amine derivative.

7. The method for fabricating a semiconductor device of claim 1,
wherein said nitrogen-containing layer is formed by implanting nitrogen ions into said exposed portion.

8. (canceled)

9. The method for fabricating a semiconductor device of claim 1,
wherein said organic silicon compound is formed of an organic silicon compound having any one selected from the organic group consisting of an ethyl group, a propyl group, a butyl group (including a cyclobutyl group), a pentyl group (including a cyclopentyl group), a hexyl group (including a cyclohexyl group), and vinyl group, a derivative of a vinyl group, a phenyl group and a derivative of a phenyl group.
